(19) United States
(12) Patent Application Publication
(10) Pub. No.: US 2008/0023754 A1
(43) Pub. Date: Jan. 31, 2008

(54) Semiconductor device with a wave-shaped trench or gate and method for manufacturing the same

(75) Inventor: Seung Joo Baek, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/819,429

(22) Filed: Jun. 27, 2007

(30) Foreign Application Priority Data
Jul. 28, 2006 (KR) 10-2006-0071549

(51) Int. Cl. H01L 29/78; H01L 21/336

(52) U.S. Cl. 257/330; 438/270; 257/E21.41; 257/E29.262

(57) ABSTRACT

A semiconductor device and a method for manufacturing the same includes forming a trench for forming a fin-type active region to have a wave shape to not connect a gate to an active region, thereby improving the speed of current flowing in the gate and reduce leakage current in a storage electrode. Additionally, the active region is expanded toward the length-wise direction to secure a sufficient storage node contact.

### RELATED APPLICATIONS

The present application claims the benefit of priority to Korean patent application number 10-2006-0071549, filed on Jul. 28, 2006, which is incorporated herein by reference in its entirety.

### BACKGROUND

The present invention generally relates to a semiconductor device and a method for manufacturing the same, and more specifically, to a semiconductor device and a method for manufacturing the same which includes forming a wave-shaped trench or a wave-shaped gate for forming a fin-type active region which is expanded along the length-wise direction.

Due to high integration of semiconductor devices, the process margin for forming an active region and a device isolation structure has been reduced.

While a gate critical dimension has been small, a channel length has been reduced, which results in a short channel effect where electric characteristics of semiconductor devices are degraded.

In order to remove the short channel effect, a Multi-channel FET (McFET) including a recess gate and a fin-type gate has been used.

The recess gate is obtained by etching a local gate region of a semiconductor substrate to a given depth to increase the channel length.

A fin-type gate is obtained by forming a fin-shaped active region to increase the contact area between gates, thereby improving the driving capacity of the gates and electric characteristics of semiconductor devices.

FIGS. 1a and 1b are plane diagrams illustrating a conventional semiconductor device. FIG. 1a is a plane diagram illustrating a semiconductor device having a trench for forming a fin-type active region, and FIG. 1b is a plane diagram illustrating a semiconductor device having a gate.

A device isolation structure 30 that defines a bar-type active region 20 is formed over a semiconductor substrate 10. Active region 20 is arranged as an island region.

Device isolation structure 30 is etched to a given depth along a region where a gate 40 is formed so that a trench T for forming the fin-type active region 20 is formed. Gate 40 is formed over trench T and active region 20.

FIGS. 2a and 2b are cross-sectional diagrams illustrating a conventional semiconductor device having a fin-type gate. FIG. 2a is a cross-sectional diagram of X-X′ of FIG. lb, and FIG. 2b is a cross-sectional diagram of Y-Y′ of FIG. 1b.

A device isolation structure 31 that defines a bar-type active region 21 is formed over a semiconductor substrate 11.

Device isolation structure 31 having a gate 41 is etched to a given depth to form a fin-type active region 21.

A gate oxide film 51 is formed over active region 21, and gate 41 is formed over active region 21 and device isolation structure 31. Gate 41 is connected to an adjacent active region 21, which can cause an interference phenomenon.

This can decrease the current speed of gate 41 and generate leakage current in a storage node region.

FIGS. 3a and 3b are cross-sectional diagrams illustrating a conventional semiconductor device having a saddle-type gate. FIG. 3a is a cross-sectional diagram of X-X′ of FIG. 1b, and FIG. 3b is a cross-sectional diagram of Y-Y′ of FIG. 1b.

A device isolation structure 32 that defines a bar-type active region 22 is formed over a semiconductor substrate 12.

Device isolation structure 32 is etched to a given depth to form a fin-type active region 22.

Active region 22 is etched to form a recess region.

A gate oxide film 52 is formed over active region 22, and a saddle-type gate 42 is formed over fin-type active region 22, the recess region, and device isolation structure 32.

In saddle-type gate 42, an operation voltage is increased, but a parasitic capacitor is generated.

FIGS. 4a and 4b are cross-sectional diagrams illustrating a conventional semiconductor device having a recess-type gate. FIG. 4a is a cross-sectional diagram of X-X′ of FIG. 1b, and FIG. 4b is a cross-sectional diagram of Y-Y′ of FIG. 1b.

A device isolation structure 33 that defines a bar-type active region 23 is formed over a semiconductor substrate 13.

Active region 23 is etched to form a recess region.

A gate oxide film 53 is formed over active region 23, and a recess-type gate 43 is formed over the recess and device isolation structure 33.

Recess-type gate 43 formed over device isolation structure 33 is connected to the edge of active region 23 without securing a sufficient storage node contact area. Leakage current is thus increased in the storage node contact, degrading refresh characteristics.

FIGS. 5a and 5b are cross-sectional diagrams illustrating a conventional semiconductor device having a bulb recess-type gate. FIG. 5a is a cross-sectional diagram of X-X′ of FIG. 1b, and FIG. 5b is a cross-sectional diagram of Y-Y′ of FIG. 1b.

A device isolation structure 34 that defines a bar-type active region 24 is formed over a semiconductor substrate 14.

Active region 24 is etched to form a recess region.

The recess region is further etched by an isotropic etching process to form a bulb recess region.

A gate oxide film 54 is formed over active region 24, and a bulb recess-type gate 44 is formed over the bulb recess region and device isolation structure 34.

The operation current of bulb recess-type gate 44 is higher than that of recess-type gate 43. However, like recess-type gate 43, bulb recess-type gate 44 formed over device isolation structure 34 is connected to the edge of active region 24 without securing a sufficient storage node contact area. The leakage current of the storage node contact is thus increased, degrading refresh characteristics of the semiconductor device.

### SUMMARY

Embodiments of the present invention provide a semiconductor device and a method for manufacturing the same which includes forming a wave-shaped trench for forming a fin-type active region to prevent a gate from being connected to an adjacent active region, thereby improving the speed of current flowing in the gate and reducing leakage current in storage nodes to improve refresh characteristics of the semiconductor device.

Further embodiments of the present invention provide a semiconductor device and a method for manufacturing the same which includes expanding a region of the active region along the length-wise direction to secure a sufficient area of a storage node contact, thereby increasing the process margin of the semiconductor device and improving electric characteristics of the semiconductor device.

Consistent with an embodiment of the present invention, a semiconductor device comprises a bar-type active region formed over a semiconductor substrate, a device isolation structure which defines the active region, a trench having a concave wave shape in a part adjacent to both ends of the length-wise direction of the active region by etching a portion of the device isolation structure, and a gate formed over the trench and the active region.

Consistent with an embodiment of the present invention, a semiconductor device comprises a bar-type active region formed over a semiconductor substrate, a device isolation structure which defines the active region, and a gate formed over the active region and the device isolation structure, and the gate having a concave wave shape in a part adjacent to both ends of the length-wise direction of the active region. The active region is expanded along the length-wise direction to be closer to the concave part of the gate.

Consistent with an embodiment of the present invention, a semiconductor device comprises a bar-type active region formed over a semiconductor substrate, a device isolation structure which defines the active region, and a gate formed over the active region and the device isolation structure, and the gate having a concave wave shape in a part adjacent to both ends of the length-wise direction of the active region and a convex wave shape in the opposition part. The active region is expanded along the length-wise direction to be closer to the concave part of the gate.

Consistent with an embodiment of the present invention, a method for manufacturing a semiconductor device comprises the steps of: forming a device isolation structure that defines a bar-type active region over a semiconductor substrate; etching a portion of the device isolation structure to form a trench having a concave wave shape at a part adjacent to both ends of the length-wise direction of the active region; and forming a gate over the trench and the device isolation structure.

Consistent with an embodiment of the present invention, a method for manufacturing a semiconductor device comprises the steps of: forming a device isolation structure that defines a bar-type active region over a semiconductor substrate; and forming a gate having a concave wave shape at a part adjacent to both ends of the length-wise direction of the active region over the active region and the device isolation structure. In forming the device isolation structure, the active region is expanded along the length-wise direction to be closer to the concave part of the gate.

Consistent with an embodiment of the present invention, a method for manufacturing a semiconductor device comprises the steps of: forming a device isolation structure that defines a bar-type active region over a semiconductor substrate; and forming a gate having a concave wave shape in a part adjacent to both ends of the length-wise direction of the active region and a convex wave shape in the opposite part over the active region and the device isolation structure. In forming the device isolation structure, the active region is expanded along the length-wise direction to be closer to the concave part of the gate.

### BRIEF DESCRIPTION OF THE DRAWINGS

FIGS. 1a and 1b are plane diagrams illustrating a conventional semiconductor device.

FIGS. 2a and 2b are cross-sectional diagrams illustrating a conventional semiconductor device having a fin-type gate.

FIGS. 3a and 3b are cross-sectional diagrams illustrating a conventional semiconductor device having a saddle-type gate.

FIGS. 4a and 4b are cross-sectional diagrams illustrating a conventional semiconductor device having a recess-type gate.

FIGS. 5a and 5b are cross-sectional diagrams illustrating a conventional semiconductor device having a bulb recess-type gate.

FIGS. 6a and 6b are plane diagrams illustrating a semiconductor device consistent with an embodiment of the present invention.

FIGS. 7a and 7b are cross-sectional diagrams illustrating a semiconductor device having a fin-type gate consistent with an embodiment of the present invention.

FIGS. 8a and 8b are cross-sectional diagrams illustrating a semiconductor device having a saddle-type gate consistent with an embodiment of the present invention.

FIGS. 9a and 9b are cross-sectional diagrams illustrating a semiconductor device having a bulb recess-type gate consistent with an embodiment of the present invention.

FIG. 10 is a plane diagram illustrating a semiconductor device consistent with an embodiment of the present invention.

FIGS. 11a and 11b are cross-sectional diagrams illustrating a semiconductor device having a normal type gate consistent with an embodiment of the present invention.

FIGS. 12a and 12b are cross-sectional diagrams illustrating a semiconductor device having a recess-type gate consistent with an embodiment of the present invention.

FIGS. 13a and 13b are cross-sectional diagrams illustrating a semiconductor device having a bulb recess-type gate consistent with an embodiment of the present invention.

FIG. 14 is a plane diagram illustrating a semiconductor device consistent with an embodiment of the present invention.

FIGS. 15a and 15b are cross-sectional diagrams illustrating a semiconductor device having a normal type gate consistent with an embodiment of the present invention.

FIGS. 16a and 16b are cross-sectional diagrams illustrating a semiconductor device having a recess-type gate consistent with an embodiment of the present invention.

FIGS. 17a and 17b are cross-sectional diagrams illustrating a semiconductor device having a bulb recess-type gate consistent with an embodiment of the present invention.

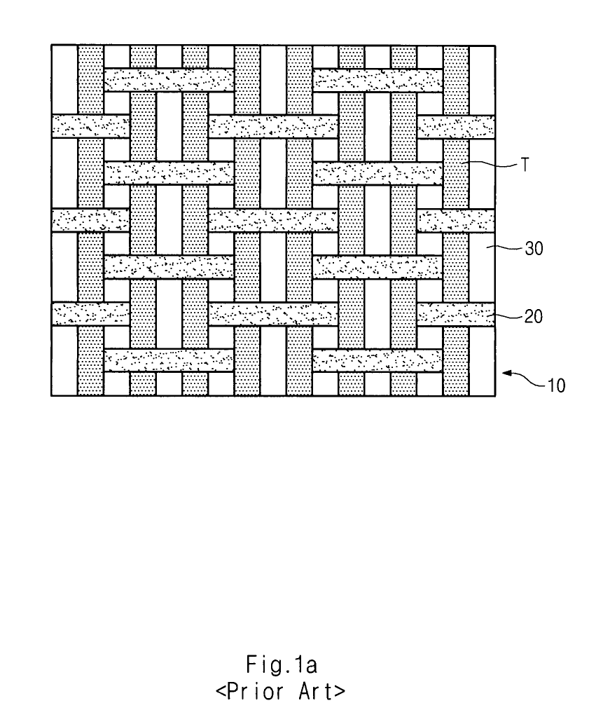

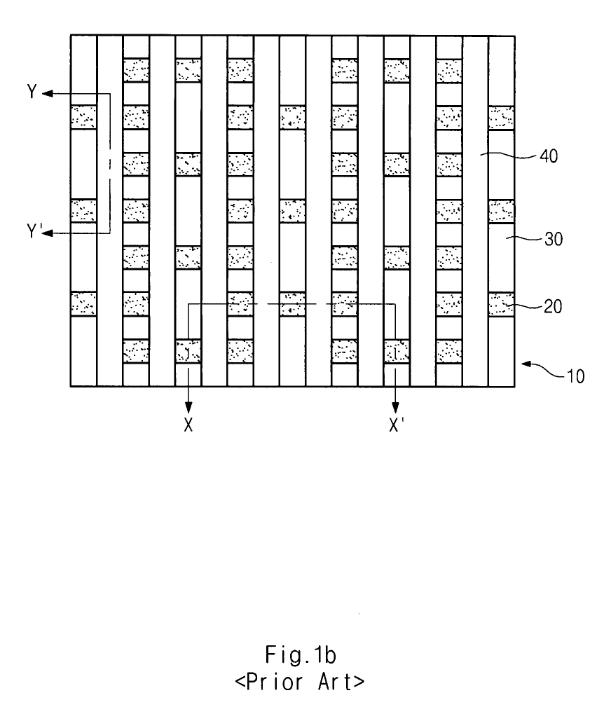

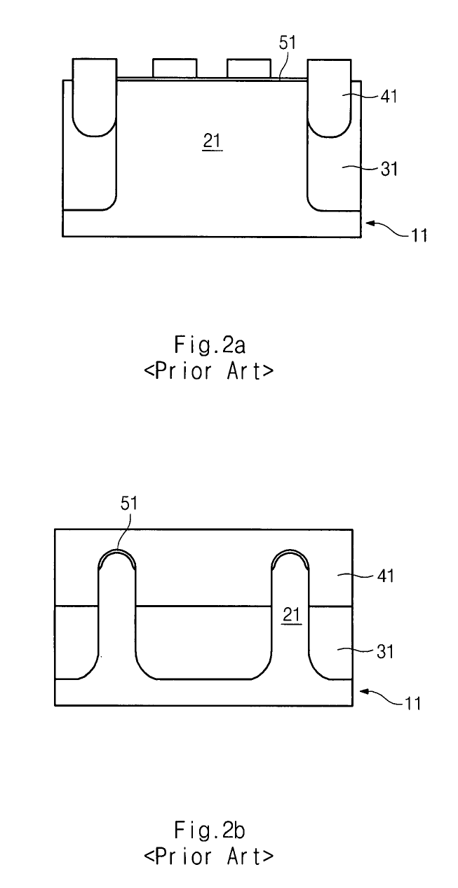

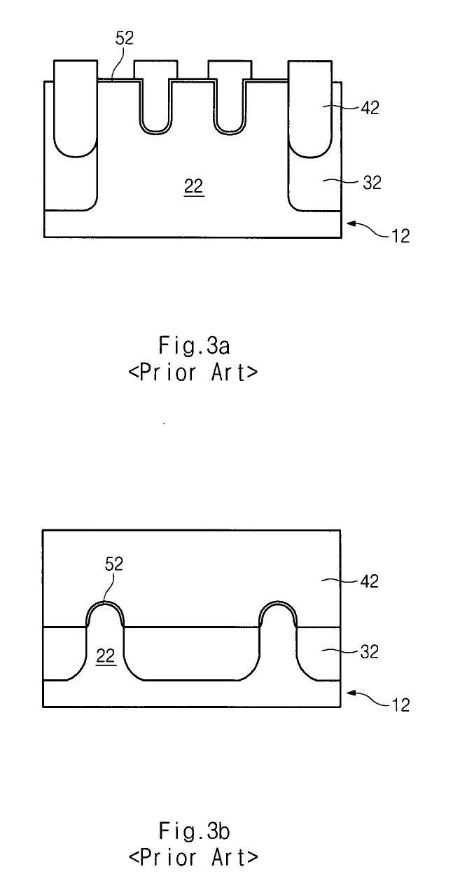

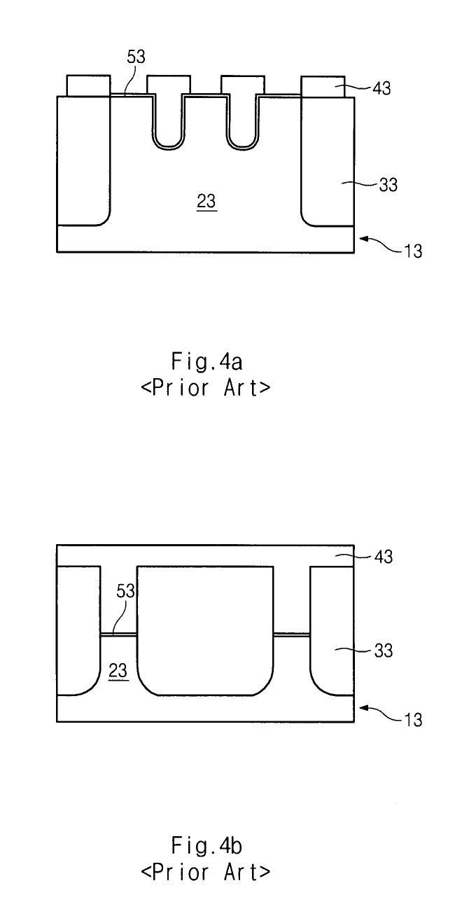

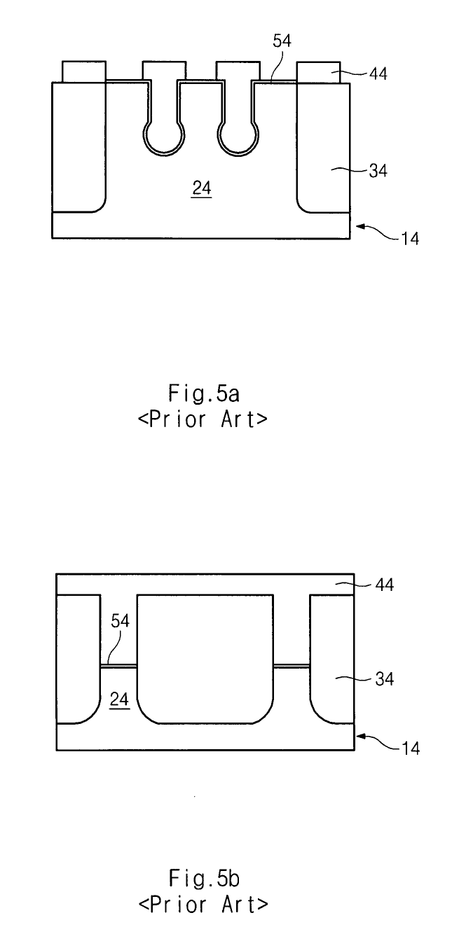

### DETAILED DESCRIPTION

Embodiments consistent with the present invention will be described in detail with reference to the accompanying drawings.

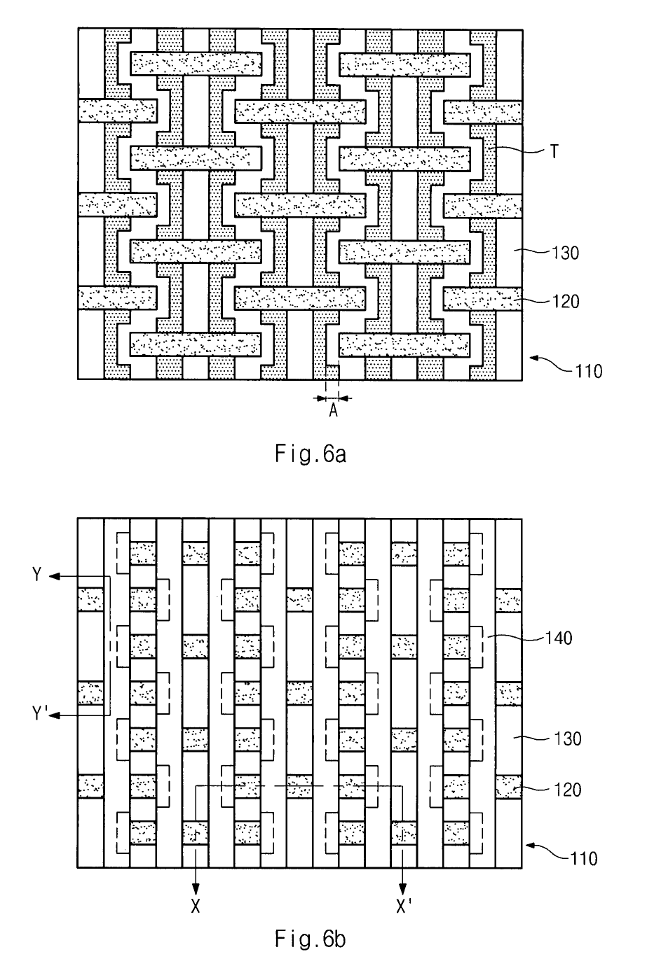

FIGS. 6a and 6b are plane diagrams illustrating a semiconductor device consistent with an embodiment of the present invention.

A device isolation structure 130 that defines a bar-type active region 120 is formed over a semiconductor substrate 110. Active region 120 is arranged as an island region.

Device isolation structure 130 is formed by a Shallow Trench Isolation (STI) process. That is, device isolation structure 130 has a trench to isolate a device, and an oxide film is filled in the trench by a High Density Plasma (HDP) process.

Device isolation structure 130 is etched to a given depth to form a trench T for forming a fin-type active region 120.

Trench T is formed to have a concave wave shape at a part adjacent to both ends of the active region 120.

A separation distance A between the part of trench T having a concave wave shape and fin-type active region 120 is less than half of a gate critical dimension used in a subsequent process.

A gate 140 is formed over trench T, fin-type active region 120, and device isolation structure 130.

In forming gate 140, a gate oxide film is formed over semiconductor substrate 110. A gate polysilicon layer, a gate metal layer, and a hard mask layer are formed over the gate oxide film. The hard mask layer, the gate metal layer, and the gate polysilicon layer are etched by an etching process using a gate mask to obtain gate 140.

Gate 140 formed over device isolation structure 130 is not connected to fin-type active region 120 to improve the speed of current flowing in gate 140 and to prevent leakage current in the electrode region.

Although gate 140 has a given line-width in this embodiment, gate 140 can be formed to have a concave wave shape in a part adjacent to both ends of the length-wise direction of active region 120, similar to trench T, or to have a convex wave shape in the opposite part.

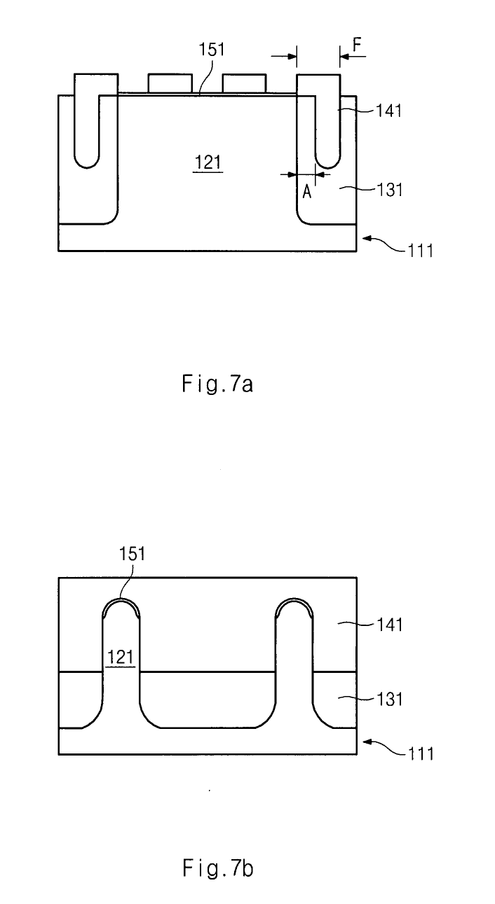

FIGS. 7a and 7b are cross-sectional diagrams illustrating a semiconductor device having a fin-type gate consistent with an embodiment of the present invention. FIG. 7a is a cross-sectional diagram of X-X′ of FIG. 6b, and FIG. 7b is a cross-sectional diagram of Y-Y′ of FIG. 6b.

A device isolation structure 131 that defines a bar-type active region 121 is formed over a semiconductor substrate 111.

Device isolation structure 131 is etched to form fin-type active region 121. Device isolation structure 131 is separated by distance A from a part adjacent to both ends of the length-wise direction of active region 121.

A gate oxide film 151 is formed over active region 121, and a fin-type gate 141 is formed over trench T, active region 121, and device isolation structure 131.

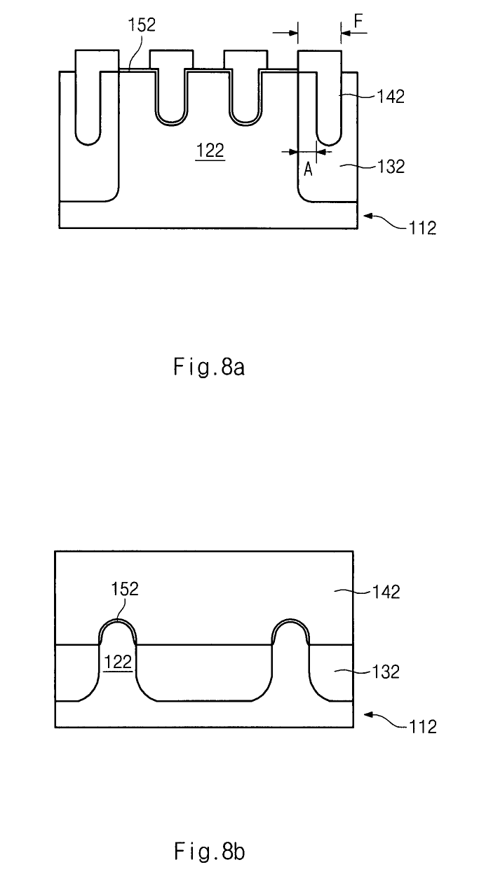

FIGS. 8a and 8b are cross-sectional diagrams illustrating a semiconductor device having a saddle-type gate consistent with an embodiment of the present invention. FIG. 8a is a cross-sectional diagram of X-X′ of FIG. 6b, and FIG. 8b is a cross-sectional diagram of Y-Y′ of FIG. 6b.

A device isolation structure 132 that defines a bar-type active region 122 is formed over a semiconductor substrate 112.

Device isolation structure 132 is etched to form a fin-type active region 122. Device isolation structure 132 is separated by distance A from a part adjacent to both ends of the length-wise direction of active region 122.

Active region 122 is etched to a given depth to form a recess region.

A gate oxide film 152 is formed over active region 122 and the recess region, and a saddle-type gate 142 is formed over trench T and the recess region.

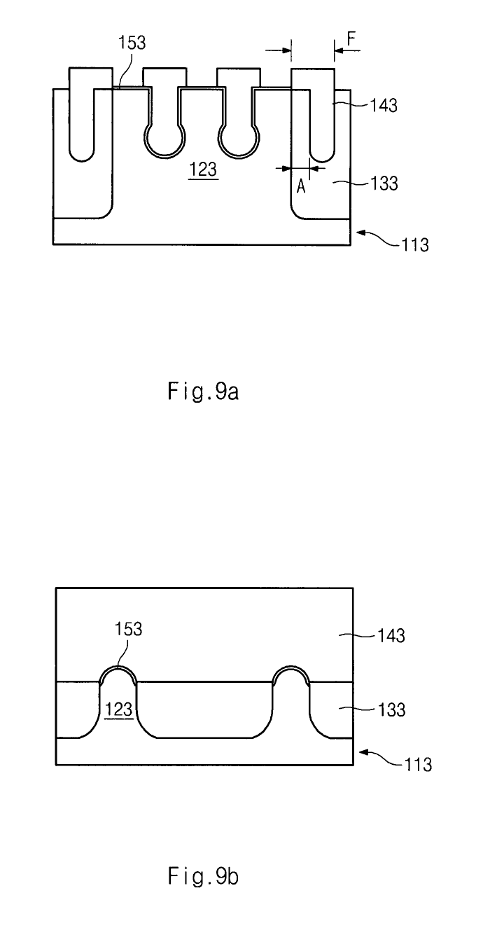

FIGS. 9a and 9b are cross-sectional diagrams illustrating a semiconductor device having a bulb recess-type gate. FIG. 9a is a cross-sectional diagram of X-X′ of FIG. 6b, and FIG. 9b is a cross-sectional diagram of Y-Y′ of FIG. 6b.

A device isolation structure 133 that defines a bar-type active region 123 is formed over a semiconductor substrate 113.

Device isolation structure 133 is etched to form a fin-type active region 123. Device isolation structure 133 is separated by distance A from a part adjacent to both ends of active region 123.

Active region 123 is etched to a given depth to form a recess region.

The recess region is further etched by an isotropic etching process to form a bulb recess region.

A gate oxide film 153 is formed over active region 123 and the recess region, and a bulb-type gate 143 is formed over trench T, the bulb recess region, and device isolation structure 133.

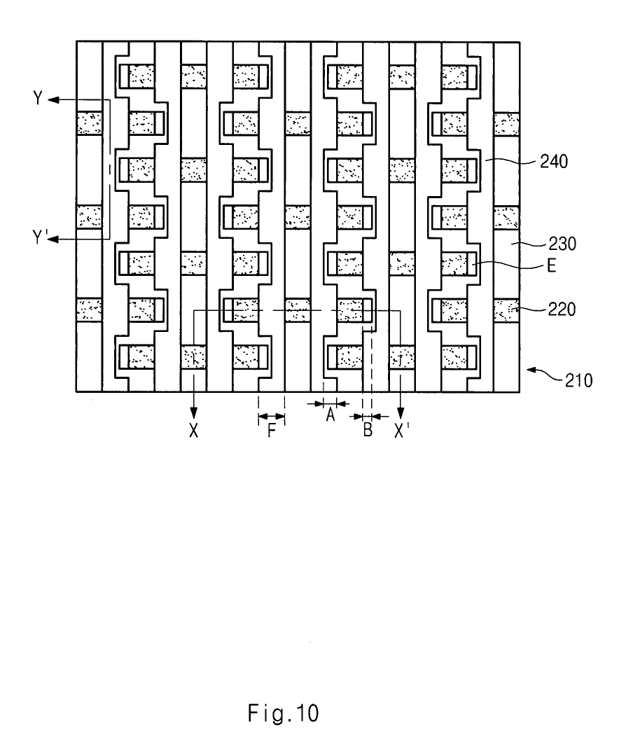

FIG. 10 is a plane diagram illustrating a semiconductor device consistent with an embodiment of the present invention.

A device isolation structure 230 that defines a bar-type active region 220 is formed over a semiconductor substrate 200. Active region 220 is arranged as an island region.

Device isolation structure 230 is formed by a Shallow Trench Isolation (STI) process. That is, a trench for separating a device is formed, and an oxide film is filled in the trench by a High Density Plasma (HDP) process, thereby obtaining device isolation structure 230.

Active region 220 is etched to form a recess region.

A gate 240 is crossed with active region 220. Gate 240 is formed to have a concave wave shape separated by distance A from a part adjacent to both ends of the length-wise direction of active region 220.

Active region 220 is expanded by a distance B along the length-wise direction to be closer to gate 240. Distance B of the expanded region E of active region 220 is set to be less than half of the line-width F of gate 240.

Gate 240 formed over device isolation structure 230 is not connected to active region 220 to improve the speed of current flowing in gate 240 and to prevent leakage current in an electrode region.

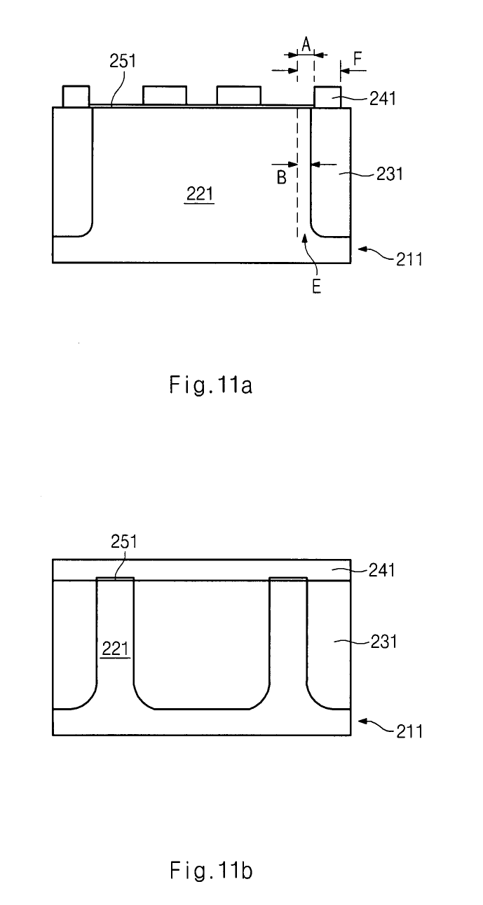

FIGS. 11a and 11b are cross-sectional diagrams illustrating a semiconductor device having a normal type gate consistent with an embodiment of the present invention. FIG. 11a is a cross-sectional diagram of X-X′ of FIG. 10, and FIG. 11b is a cross-sectional diagram of Y-Y′ of FIG. 10.

A device isolation structure 231 that defines an active region 221 is formed over a semiconductor substrate 211.

A gate oxide film 251 is formed over active region 221, and a normal type gate 241 is formed over active region 221 and device isolation structure 231.

Gate 241 is crossed with active region 221. Gate 241 is formed to have a concave wave shape separated by distance A from a part adjacent to both ends of the length-wise direction of active region 221.

Gate oxide film 251 is formed over semiconductor substrate 211. A gate polysilicon layer, a gate metal layer, and a hard mask layer are formed over gate oxide film 251. The hard mask layer, the gate metal layer, and the gate polysilicon layer are etched by an etching process using a gate mask to obtain gate 241.

Active region 221 is expanded by distance B along the length-wise direction to be closer to gate 241. Distance B of expanded region E of active region 221 is set to be less than half of line-width F of gate 241.

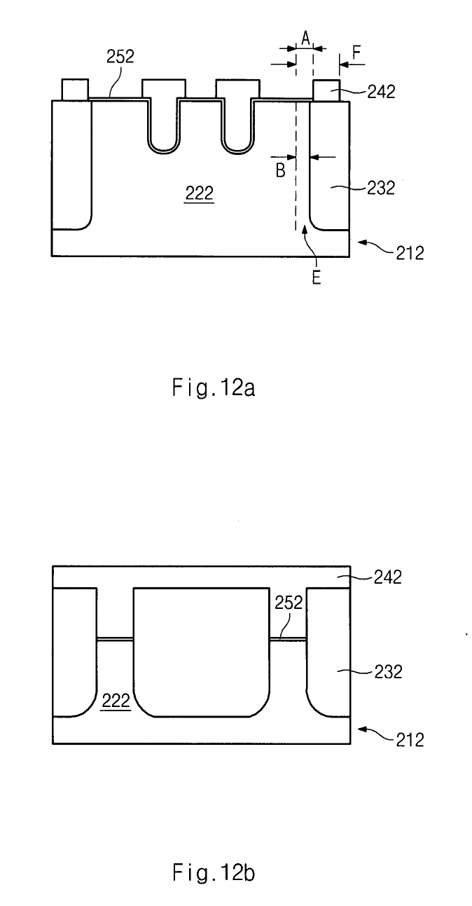

FIGS. 12a and 12b are cross-sectional diagrams illustrating a semiconductor device having a recess-type gate.

FIG. 12a is a cross-sectional diagram of X-X′ of FIG. 10, and FIG. 12b is a cross-sectional diagram of Y-Y′ of FIG. 10.

A device isolation structure 232 that defines a bar-type active region 222 is formed over a semiconductor substrate 212.

Active region 222 is etched to form a recess region.

A gate oxide film 252 is formed over active region 222 and the recess region, and a recess-type gate 242 is formed over the recess region and device isolation structure 232.

Gate oxide film 252 is formed over semiconductor substrate 212. A gate polysilicon layer, a gate metal layer, and a hard mask layer are formed over gate oxide film 252. The hard mask layer, the gate metal layer, and the gate polysilicon layer are etched by an etching process using a gate mask to obtain gate 242.

Gate 242 is formed to have a concave wave shape separated by distance A from a part adjacent to both ends of the length-wise direction of active region 222.

Active region 222 is expanded by distance B along the length-wise direction to be closer to gate 242. Distance B of expanded region E of active region 222 is set to be less than half of line-width F of gate 242.

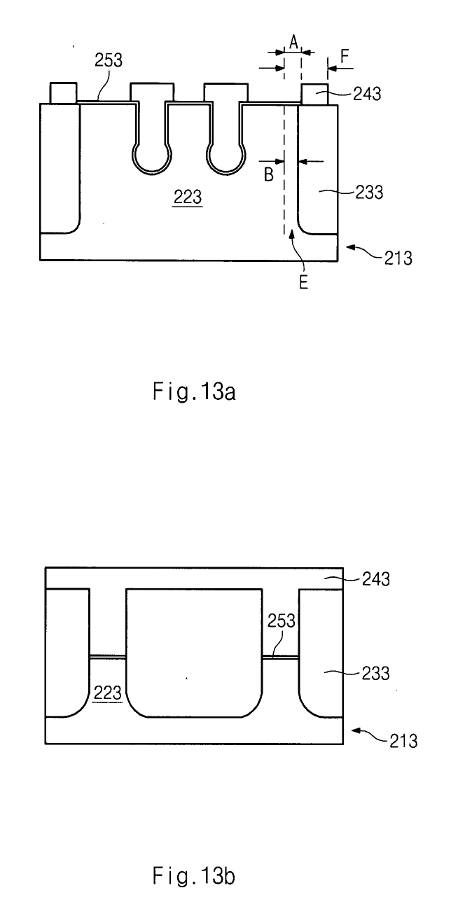

FIGS. 13a and 13b are cross-sectional diagrams illustrating a semiconductor device having a bulb recess-type gate. FIG. 13a is a cross-sectional diagram of X-X′ of FIG. 10, and FIG. 13b is a cross-sectional diagram of Y-Y′ of FIG. 10.

A device isolation structure 233 that defines a bar-type active region 223 is formed over a semiconductor substrate 213.

Active region 223 is etched to form a recess region. The recess region is further etched by an isotropic etching process to form a bulb recess region.

A gate oxide film 253 is formed over active region 223 and the recess region, and a bulb recess-type gate 243 is formed over the bulb recess region and device isolation structure 233.

Gate oxide film 253 is formed over semiconductor substrate 213. A gate polysilicon layer, a gate metal layer, and a hard mask layer are formed over gate oxide film 253. The hard mask layer, the gate metal layer, and the gate polysilicon layer are etched by an etching process using a gate mask to obtain gate 243.

Gate 243 is formed to have a concave wave shape separated by distance A from a part adjacent to both ends of the length-wise direction active region 223.

Active region 223 is expanded by distance B along the length-wise direction to be closer to gate 243. Distance B of expanded region E of active region 223 is set to be less than half of line-width F of gate 243.

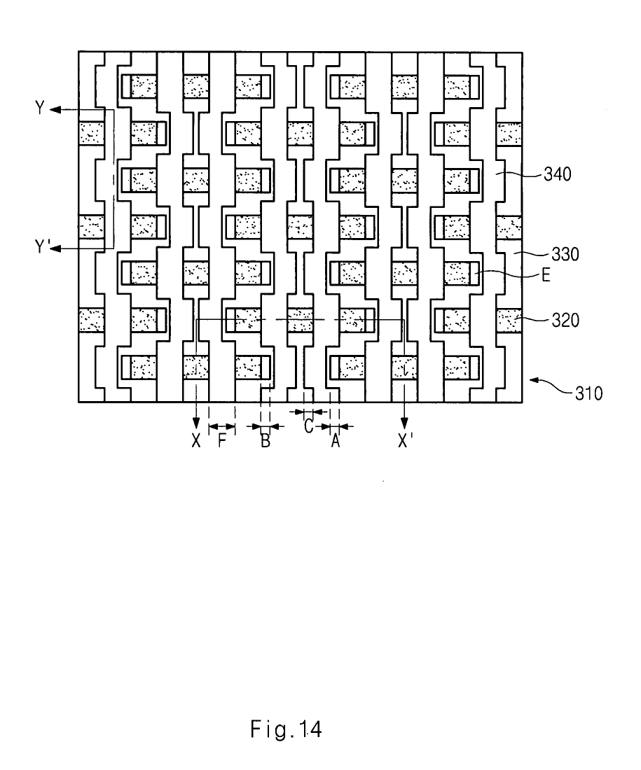

FIG. 14 is a plane diagram illustrating a semiconductor device consistent with an embodiment of the present invention.

A device isolation structure 330 that defines a bar-type active region 320 is formed over a semiconductor substrate 300. Active region 320 is arranged as an island region.

Device isolation structure 330 is formed by a Shallow Trench Isolation (STI) process. That is, a trench for separating a device is formed, and an oxide film is filled in the trench by a High Density Plasma (HDP) process, thereby obtaining device isolation structure 330.

A gate 340 is crossed with active region 320. Gate 340 is formed to have a concave wave shape separated by distance A from a part adjacent to both ends of the length-wise direction of active region 320.

Also, gate 340 is formed to have a convex wave shape in the opposite part. That is, active region 320 is expanded by distance B along the length-wise direction to be closer to gate 340. Here, distance B of expanded region E of active region 320 is set to be less than half of line-width F of gate 340. Thus, the reduction of line-width F of gate 340 by distance A is compensated. As a result, line-width F of gate 340 can be maintained. The distance C of the region formed to be convex is set to be less than half of line-width F of gate 340 within a range which is not connected to an adjacent gate 340.

Gate 340 formed over device isolation structure 330 is not connected to active region 320 to improve the speed of current flowing in gate 340 and to prevent leakage current in an electrode region.

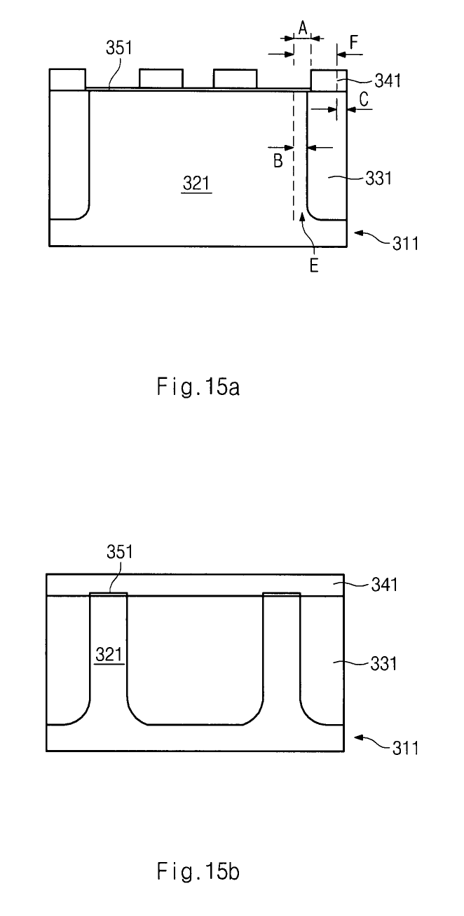

FIGS. 15a and 15b are cross-sectional diagrams illustrating a semiconductor device having a normal type gate consistent with an embodiment of the present invention. FIG. 15a is a cross-sectional diagram of X-X′ of FIG. 14, and FIG. 15b is a cross-sectional diagram of Y-Y′ of FIG. 14.

A device isolation structure 331 that defines an active region 321 is formed over a semiconductor substrate 311.

A gate oxide film 351 is formed over active region 321, and a normal type gate 341 is formed over active region 321 and device isolation structure 331.

Gate 341 is crossed with active region 321. Gate 341 is formed to have a concave wave shape separated by distance A from a part adjacent to both ends of the length-wise direction of active region 321, and to have a convex wave shape expanded by distance C in the opposite part to compensate the line-width of gate 341 by distance A. As a result, the line-width of gate 341 can be maintained. Distance C of the region formed to be convex is set to be less than half of the line-width of gate 341 to not be connected to an adjacent gate 341.

Gate oxide film 351 is formed over semiconductor substrate 311. A gate polysilicon layer, a gate metal layer, and a hard mask layer are formed over gate oxide film 351. The hard mask layer, the gate metal layer, and the gate polysilicon layer are etched by an etching process using a gate mask to obtain gate 341.

Active region 321 is expanded along the length-wise direction by distance B to be closer to gate 341. Distance B of expanded region E of active region 321 is set to be less than half of line-width F of gate 341.

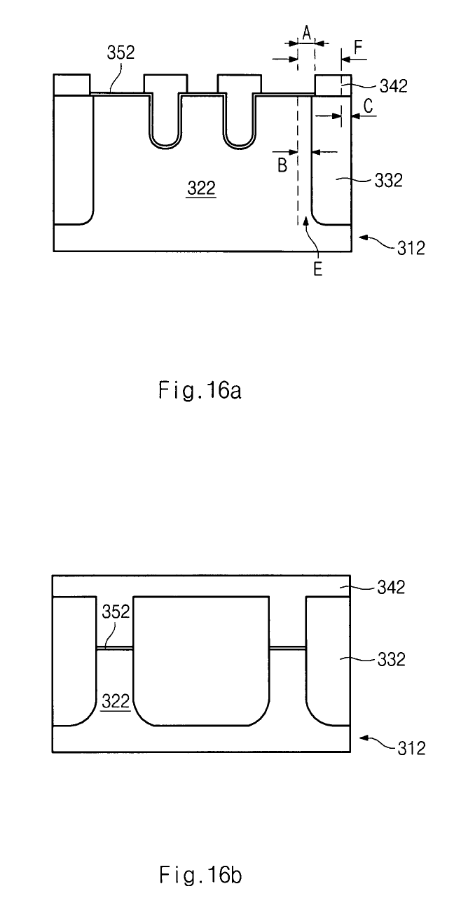

FIGS. 16a and 16b are cross-sectional diagrams illustrating a semiconductor device having a recess-type gate.

FIG. 16a is a cross-sectional diagram of X-X′ of FIG. 14, and FIG. 16b is a cross-sectional diagram of Y-Y′ of FIG. 14.

A device isolation structure 332 that defines an active region 322 is formed over a semiconductor substrate 312.

Active region 322 is etched to form a recess region.

A gate oxide film 352 is formed over active region 322 and the recess region, and recess type gate 342 is formed over the recess region and device isolation structure 332.

Gate oxide film 352 is formed over semiconductor substrate 312. A gate polysilicon layer, a gate metal layer, and a hard mask layer are formed over gate oxide film 352. The hard mask layer, the gate metal layer, and the gate polysilicon layer are etched by an etching process using a gate mask to obtain gate 342.

Gate 342 is formed to have a concave wave shape separated by distance A from a part adjacent to both ends of the length-wise direction of active region 322, and to have a convex wave shape expanded by distance C in the opposite part to compensate the line-width of the gate 342 by distance A. As a result, the line-width of gate 342 can be maintained. Distance C of the region formed to be convex is set to be less than half of the line-width of gate 342 to not be connected to an adjacent gate 342.

Active region 322 is expanded along the length-wise direction by distance B to be closer to gate 342. Distance B of expanded region E of active region 322 is set to be less than half of line-width F of gate 342.

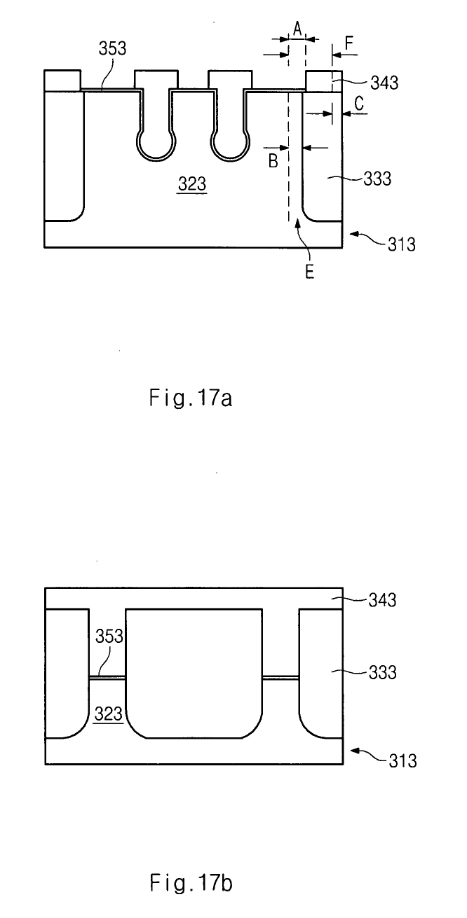

FIGS. 17a and 17b are cross-sectional diagrams illustrating a semiconductor device having a bulb recess-type gate. FIG. 17a is a cross-sectional diagram of X-X′ of FIG. 14, and FIG. 17b is a cross-sectional diagram of Y-Y′ of FIG. 14.

A device isolation structure 333 that defines an active region 323 is formed over a semiconductor substrate 313.

Active region 323 is etched to form a recess region.

The recess region is further etched by an isotropic etching process to form a bulb recess region.

A gate oxide film 353 is formed over active region 323 and the bulb recess region, and a bulb-type gate 343 is formed over the bulb recess region and device isolation structure 333.

Gate oxide film 353 is formed over semiconductor substrate 313. A gate polysilicon layer, a gate metal layer, and a hard mask layer are formed over gate oxide film 353. The hard mask layer, the gate metal layer, and the gate polysilicon layer are etched by an etching process using a gate mask to obtain gate 343.

Gate 343 is formed to have a concave wave shape separated by distance A from a part adjacent to both ends of the length-wise direction of active region 323, and to have a convex wave shape expanded by distance C in the opposite part to compensate the line-width of gate 343 by distance A. As a result, the line-width of gate 343 can be maintained. Distance C of the region formed to be convex is set to be less than half of the line-width of gate 343 to not be connected to an adjacent gate 343.

Active region 323 is expanded along the length-wise direction by distance B to be closer to bulb recess-type gate 343. Distance B of expanded region E of active region 323 is set to be less than half of line-width F of gate 343.

As described above, in a semiconductor device and a method for manufacturing the same consistent with an embodiment of the present invention, a trench for forming a fin-type active region is formed to have a wave shape to not connect a gate to an active region, thereby improving the speed of current flowing in the gate and reduce leakage current in a storage node to improve refresh characteristics of semiconductor devices.

Additionally, an active region may be expanded along the length-wise direction by a given distance to secure a sufficient storage node contact, thereby increasing the process margin of semiconductor devices and improving electric characteristics of semiconductor devices.

The above embodiments of the present invention are illustrative and not limitative. Various alternatives and equivalents are possible. The invention is not limited by the lithography steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a bar-type active region formed over a semiconductor substrate;
a device isolation structure which defines the active region;
a trench having a concave wave shape in a part adjacent to both ends of a length-wise direction of the active region formed by etching a portion of the device isolation structure; and
a gate formed over the trench and the active region.

2. The semiconductor device according to claim 1, wherein the trench is separated from both ends of the length-wise direction of the active region by a distance that is less than half of the gate width.

3. The semiconductor device according to claim 1, wherein the trench further comprises a recess region where a portion of the active region which overlaps the gate is etched.

4. The semiconductor device according to claim 1, wherein the trench further comprises a bulb recess region where a portion of the active region which overlaps the gate is etched.

5. The semiconductor device according to claim 1, wherein the gate has a concave wave shape in a part adjacent to both ends of the length-wise direction of the active region.

6. The semiconductor device according to claim 1, wherein the gate is concave in a part adjacent to both ends of the length-wise direction of the active region and convex in the opposite part.

7. A semiconductor device comprising:
a bar-type active region formed over a semiconductor substrate;
a device isolation structure which defines the active region;
a gate formed over the active region and the device isolation structure, the gate having a concave wave shape in a part adjacent to both ends of a length-wise direction of the active region,
wherein the active region is expanded along the length-wise direction to be closer to the concave part of the gate.

8. The semiconductor device according to claim 7, wherein a width of the expanded part of the active region is less than half of the gate width.

9. The semiconductor device according to claim 7, wherein the active region has a recess region where a portion of the active region which overlaps the gate is etched.

10. The semiconductor device according to claim 7, wherein the active region has a bulb recess region where a portion of the active region which overlaps the gate is etched.

11. A semiconductor device comprising:
a bar-type active region formed over a semiconductor substrate;
a device isolation structure which defines the active region;
a gate formed over the active region and the device isolation structure, the gate having a concave wave shape in a part adjacent to both ends of a length-wise direction of the active region and a convex wave shape in the opposition part,
wherein the active region is expanded along the length-wise direction to be closer to the concave part of the gate.

12. The semiconductor device according to claim 11, wherein a width of the expanded part of the active region is less than half of the gate width.

13. The semiconductor device according to claim 11, wherein the active region has a recess region where a portion of the active region which overlaps the gate is etched.

14. The semiconductor device according to claim 11, wherein the active region has a bulb recess region where a portion of the active region which overlaps the gate is etched.

15. The semiconductor device according to claim 11, wherein a width of the convex part of the gate is less than half of the gate width.

16. A method for manufacturing a semiconductor device, the method comprising the steps of:
forming a device isolation structure that defines a bar-type active region over a semiconductor substrate;
etching a portion of the device isolation structure to form a trench having a concave wave shape at a part adjacent to both ends of a length-wise direction of the active region; and
forming a gate over the trench and the device isolation structure.

17. The method according to claim 16, wherein forming the trench further comprises etching a portion of the active region which overlaps the gate to form a recess region.

18. The method according to claim 16, wherein forming the trench further comprises etching a portion of the active region which overlaps the gate to form a bulb recess region.

19. The method according to claim 16, wherein the formed gate has a concave wave shape in a part adjacent to both ends of the length-wise direction of the active region.

20. The method according to claim 16, wherein the formed gate has a concave shape in a part adjacent to both ends of the length-wise direction of the active region and a convex wave shape in the opposite part.

21. A method for manufacturing a semiconductor device, the method comprising the steps of:
forming a device isolation structure that defines a bar-type active region over a semiconductor substrate; and
forming a gate having a concave wave shape at a part adjacent to both ends of a length-wise direction of the active region over the active region and the device isolation structure,
wherein the active region is expanded along the length-wise direction to be closer to the concave part of the gate.

22. The method according to claim 21, wherein forming the trench further comprises etching a portion of the active region which overlaps the gate to form a recess region.

23. The method according to claim 21, wherein forming the trench further comprises etching a portion of the active region which overlaps the gate to form a bulb recess region.

24. A method for manufacturing a semiconductor device, the method comprising the steps of:
forming a device isolation structure that defines a bar-type active region over a semiconductor substrate; and
forming a gate having a concave wave shape in a part adjacent to both ends of a length-wise direction of the active region and a convex wave shape in the opposite part over the active region and the device isolation structure,
wherein the active region is expanded along the length-wise direction to be closer to the concave part of the gate.

25. The method according to claim 24, wherein forming the trench further comprises etching a portion of the active region which overlaps the gate to form a recess region.

26. The method according to claim 24, wherein forming the trench further comprises etching a portion of the active region which overlaps the gate to form a bulb recess region.
